(19) United States
(12) Patent Application Publication
(10) Pub. No.: US 2005/0263181 A1
(43) Pub. Date: Dec. 1, 2005

(54) Photovoltaic cooling frame

(76) Inventor: Kuo-Yow Yen, Irvine, CA (US)

Correspondence Address: LAW OFFICES OF CLEMENT CHENG, 17220 NEWHOPE STREET #127, FOUNTAIN VALLEY, CA, 92708, US

(21) Appl. No.: 11/021,582

(22) Filed: Dec. 24, 2004

Related U.S. Application Data
(60) Provisional application No. 60/574,168, filed on May 25, 2004.

(51) Int. Cl. H01L 25/00

(52) U.S. Cl. 136/251

(57) ABSTRACT

A passive convection cooling system for photovoltaic panels according to the present disclosure utilizes principals of aerodynamics to channel natural air flow across photovoltaic panels to increase the rate of heat transfer and increase the convection rate and decrease the temperature of the photovoltaic panels thereby increasing the efficiency of the solar cells and decreasing failures of the photovoltaic system. The photovoltaic cooling system comprises a generally rigid frame supporting one or more photovoltaic panels creating a lower ventilation path to increase rate of heat transfer under the photovoltaic panel to greatly increase the convection rate to effectively cool the photovoltaic system. It is emphasized that this abstract is provided to comply with the rules requiring an abstract which will allow a searcher or other reader to quickly ascertain the subject matter of the technical disclosure. It is submitted with the understanding that it will not be used to interpret or limit the scope or meaning of the claims.

### RELATED APPLICATIONS

This application claims the priority of provisional patent application 60/574,168 filed May 25, 2004.

### BACKGROUND OF THE INVENTION

1. Field of the Invention

The present disclosure relates generally to a photovoltaic cooling system. More specifically, the present disclosure relates to an aerodynamic frame for passive cooling of photovoltaic panels.

2. Description of the Prior Art

The collection of solar energy may adopt many forms. A currently desirable configuration is direct conversation of solar energy to electricity using semiconductor photovoltaic panels. The heart of the photovoltaic system is a thin flat layer of semiconductor material. When the semiconductor material is struck by sunlight, electrons are freed, producing an electric current. Typically, individual solar cells may be ganged together to form photovoltaic modules. Typically, about half the cost of a solar system lies with the solar cell modules, and the remainder is directed toward power conditioning, electrical wiring, installation, and site preparation.

The energy conversion efficiency of solar cells decreases as the temperature of the solar cells increases. Furthermore, increasing temperature may also have detrimental effects on other components of the photovoltaic system, including thermal stress which may result in failures in the photovoltaic system.

Many conventional support frames are configured to create a dead air space beneath a photovoltaic panel. Air within the dead air space provides almost no convective cooling and often retains heat.

Cooling can be provided by both active and passive systems. Active cooling systems may include Rankine cycle system and absorption system, both of which require additional hardware and costs. Passive cooling systems such as convection cooling; radiative cooling; and evaporative cooling from water surfaces exposed to the atmosphere may also be used.

What is needed is a passive cooling system for photovoltaic panels to minimize or eliminate dead air space and increase passive cooling.

### SUMMARY OF THE INVENTION

In a first aspect, the present disclosure provides a rigid frame for supporting one or more photovoltaic panels, forming at least one ventilation channel between the one or more photovoltaic panels and the support plane. The frame is formed to provide rigid support while eliminating dead air space beneath the panels, and is shaped to encourage airflow across the panels and provide heat transfer from the photovoltaic element.

In another aspect, the present disclosure provides a rigid frame for supporting one or more photovoltaic panels. The rigid frame may include one or more wing surfaces to promote airflow across the panels and encourage heat transfer from the photovoltaic element in no-wind or low wind conditions. The rigid frame of the present disclosure is shaped to form a venturi between the support plane and the one or more photovoltaic panels.

In still another aspect, the present disclosure provides convective wings that may be added to a conventional photovoltaic support frame to encourage convective heat transfer from the photovoltaic element.

These and other features and advantages of this disclosure will become further apparent from the detailed description and accompanying figures that follow. In the figures and description, numerals indicate the various features of the disclosure, like numerals referring to like features throughout both the drawings and the description.

### BRIEF DESCRIPTION OF THE DRAWINGS

FIG. 1 is a perspective view of a photovoltaic cooling frame according to the present disclosure.

FIG. 2 is a perspective view of another embodiment of the photovoltaic cooling frame of FIG. 1.

FIG. 3 is a perspective view of a further embodiment of the photovoltaic cooling frame of FIG. 1.

FIG. 4 is a perspective view of another embodiment of a photovoltaic cooling frame according to the present disclosure.

FIG. 5 is a perspective view of the cooling frame of FIG. 1 with an wings added according to the present disclosure.

FIG. 6 is a perspective view of another further embodiment of a photovoltaic cooling frame according to the present disclosure.

FIG. 7 is a perspective view of another embodiment of the photovoltaic cooling frame of FIG. 6.

FIG. 8 is a perspective view of a still further embodiment of a photovoltaic cooling frame according to the present disclosure.

FIG. 9 is a cross-sectional view of the cooling frame of FIG. 3 taken along B-B′.

FIG. 10 is a cross-sectional view of the cooling frame of FIG. 7 taken along A-A′.

### DETAILED DESCRIPTION OF THE PREFERRED EMBODIMENT(S)

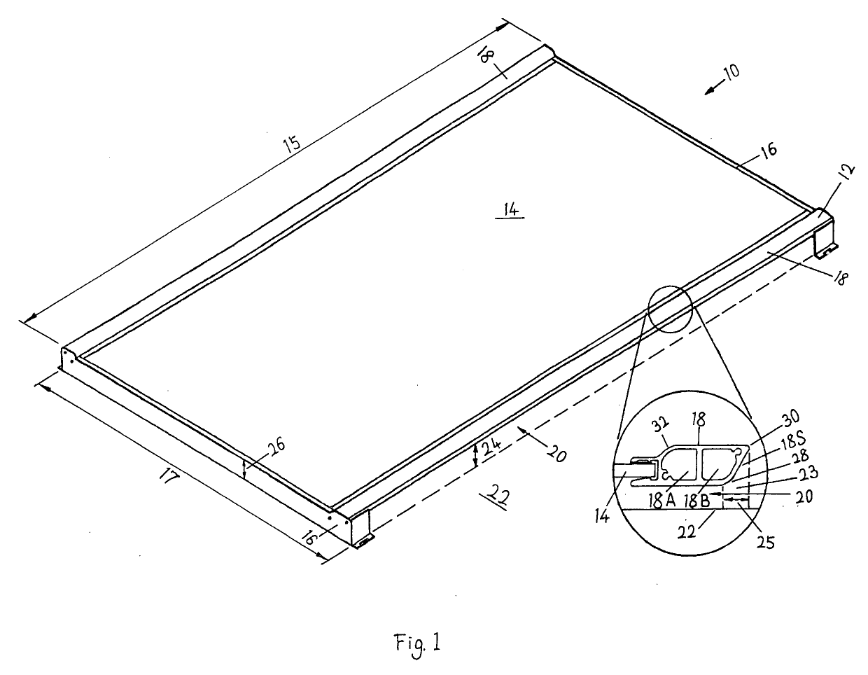

Referring now to FIG. 1, photovoltaic assembly 10 includes cooling frame 12 and one or more photovoltaic panels 14. Cooling frame 12 includes end elements 16 to connect side elements 18 and form cooling channel 20 parallel to short axis 17 between photovoltaic assembly 10 and support plane 22. Cooling channel 20 may have height 24 which may be altered by varying height 26 of end elements 16. Rounded edges 28, 30 and 32 of side elements 18 encourage smooth airflow through cooling channel 20. Slope 18S between rounded edge 28 and rounded edge 30 forms venturi 23 having depth 25. In this configuration photovoltaic assembly 10 may be oriented to place cooling channel 20 parallel prevailing wind direction along short axis 17.

Side elements 18 may be formed to include two or more closed structural channels such as structural channels 18A and 18B. Structural channels included in a cooling frame according to the present invention may have any suitable closed or open geometry. Side elements 18 also include generally coplanar lower surfaces 19. Lower surface 19 is also generally coplanar with lower surface 14B of one or more photovoltaic panels 14.

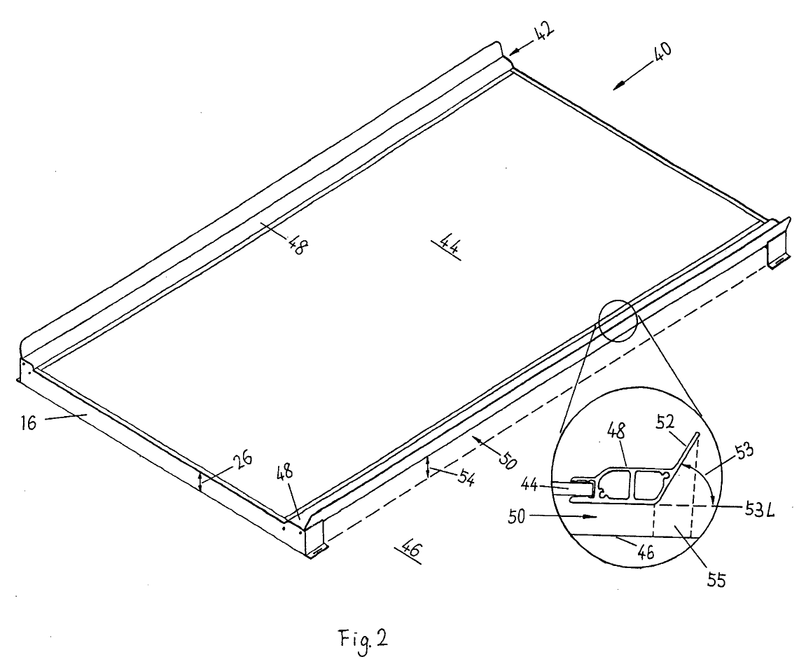

Referring now to FIG. 2, in an alternate embodiment, photovoltaic assembly 40 includes cooling frame 42 and one or more photovoltaic panels 44. Cooling frame 42 includes end elements 16 to connect side elements 48 and form cooling channel 50 between photovoltaic assembly 40 and support plane 46. Cooling channel 50 may have height 54 which may be altered by varying height 26 of end elements 16. Wing 52 extends at angle 53 from line 53L parallel to support plane 46. Wing 52 extends cooling channel 50 vertically to height 57 and horizontally to edge 59 thus forming venturi 55.

Angle 53 may be selected to optimize cooling effect and may use a number of factors such as average wind velocity, peak wind velocity, average wind duration, and others to select angle 53. A wing such as wing 52 may be formed by any suitable extension from any side or end element.

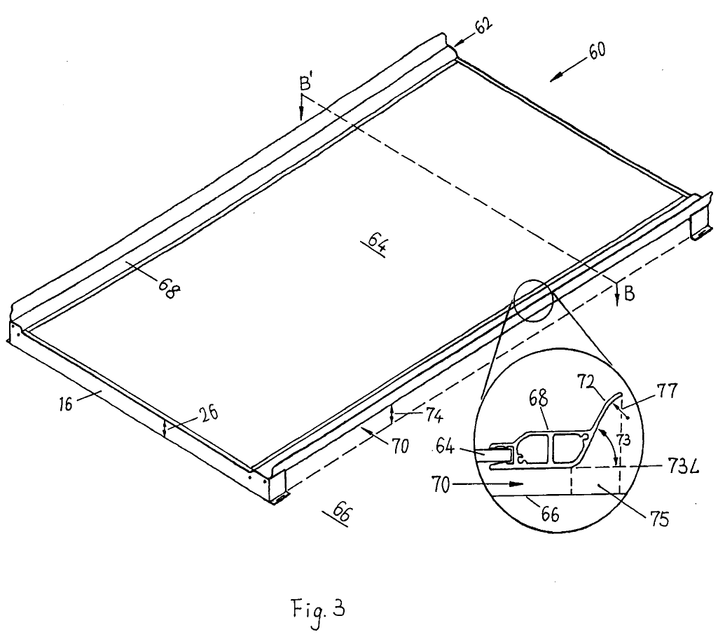

Referring now to FIG. 3, in another alternate embodiment, photovoltaic assembly 60 includes cooling frame 62 and one or more photovoltaic panels 64. Cooling frame 62 includes end elements 16 to connect side elements 68 and form cooling channel 70 between photovoltaic assembly 60 and support plane 66. Cooling channel 70 may have height 74 which may be altered by varying height 26 of end elements 16. Wing 72 extends at angle 73 from line 73L parallel to support surface 66 and may include curvature radius 77 to form venturi 75 leading to cooling channel 70. Angle 73 and curvature radius 77 may be selected to optimize cooling effect and may use factors such as average wind velocity, peak wind velocity, average wind duration, and others to select angle 73 and curvature radius 77.

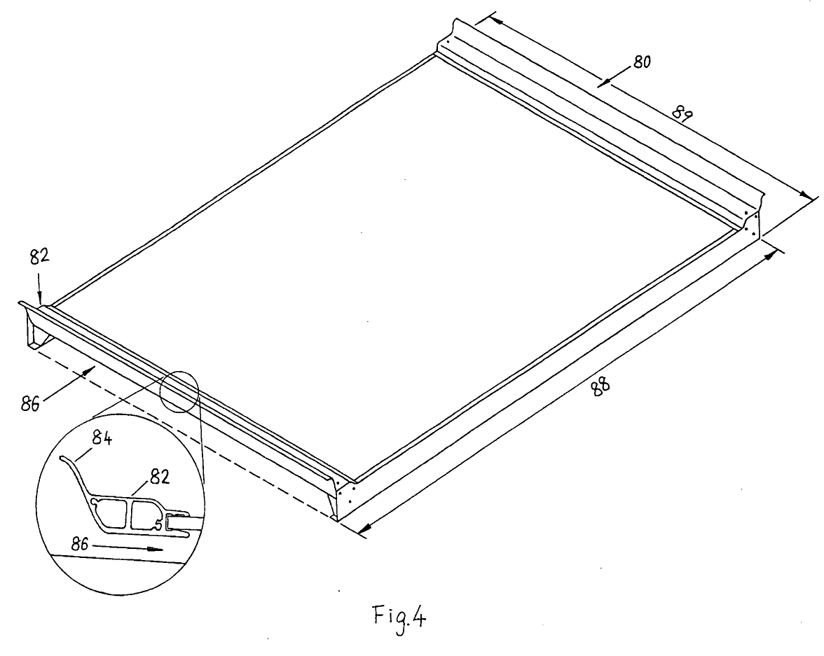

Wings such as wings 52 or 72 may be incorporated in side elements such as side elements 48 and 68 respectively. Referring now to FIG. 4, in still another alternate embodiment of the present disclosure, wings such as wing 84 may be included on end elements such as end element 82 parallel to short axis 89. In this configuration cooling channel 86 is parallel to long axis 88 and photovoltaic assembly 80 may be oriented with cooling channel generally parallel to prevailing wind direction along long axis 88.

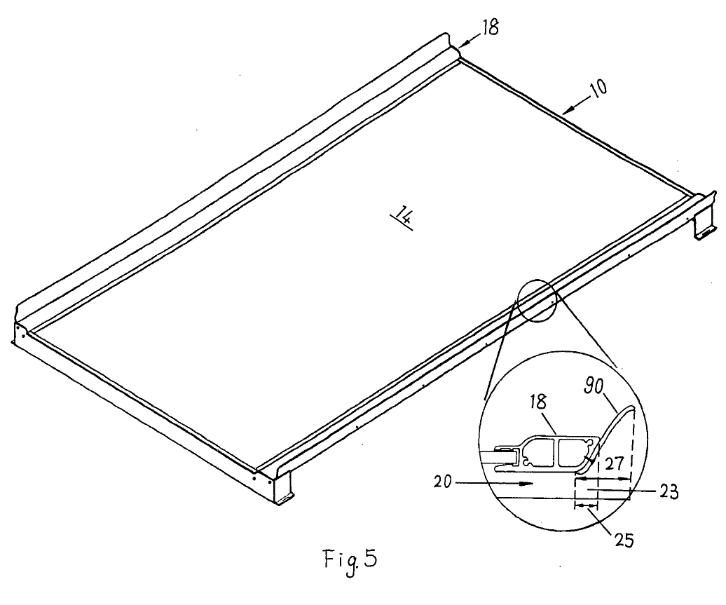

Referring now to FIG. 5, in another still alternate embodiment wing 90 may be added to side element 18 to extend venturi 23 from depth 25 to depth 27.

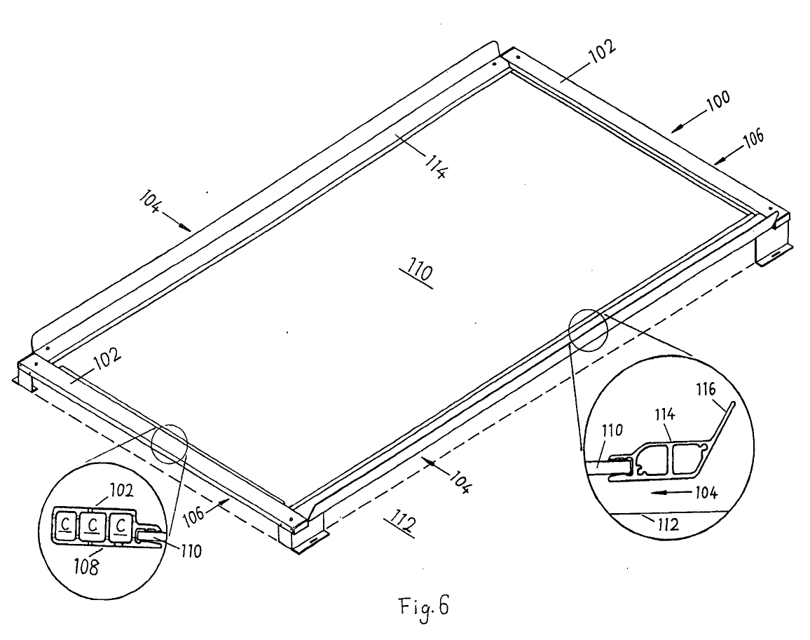

Referring now to FIG. 6, in still another alternate embodiment of the present disclosure, photovoltaic assembly 100 maximizes cooling airflow by replacing end elements 16 of FIG. 1 with open end element 102. Open end elements such as open end element 102 may be formed using two or more structural channels C to from a light and rigid structure. Using photovoltaic assembly 100, air may circulate through side access 104 or end access 106. The configuration of open end element 102 provides a large cross section 108 with a light weight, thus providing the structural stability to support fragile photovoltaic panels such as panel 110 and permit maximum cooling flow between panel 110 and surface 112.

In another aspect of the present disclosure, dead air space is minimized adjacent to bottom surface 110B of panel 110. Generally C-shaped channel 115 incorporated into side and end elements of structural frames such as photovoltaic assembly 100 secures one or more panels such as panel 110. Any other suitable configuration may be used. Channel 115 is formed to minimize transition 117 between panel bottom surface 110B and element 114 bottom surface 114B. Thus the bottom surfaces of structural elements such as bottom surface 110B of side element 114 is nearly coplanar with bottom surface of the supported panel or panels such as bottom surface 110B of panel 110.

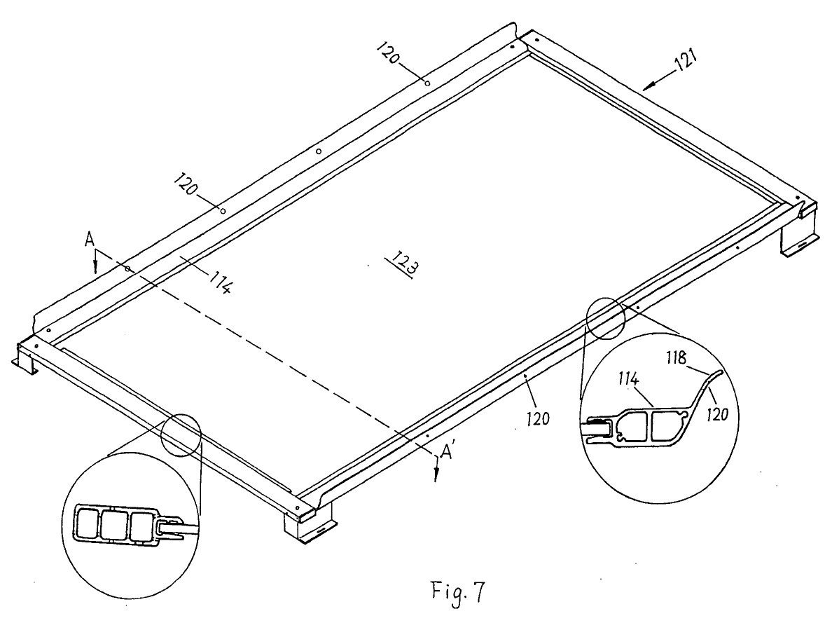

Referring now to FIG. 7, in a further alternate embodiment of the present disclosure, side elements 114 may incorporate straight wing 116 as shown in FIG. 6, or curved wing 118 as shown in FIG. 7. Wings 116, 118 or add on wings such as wing 90 may further incorporate vent holes 120 or any other suitable aerodynamic adaptation to optimize the cooling effect of the wings.

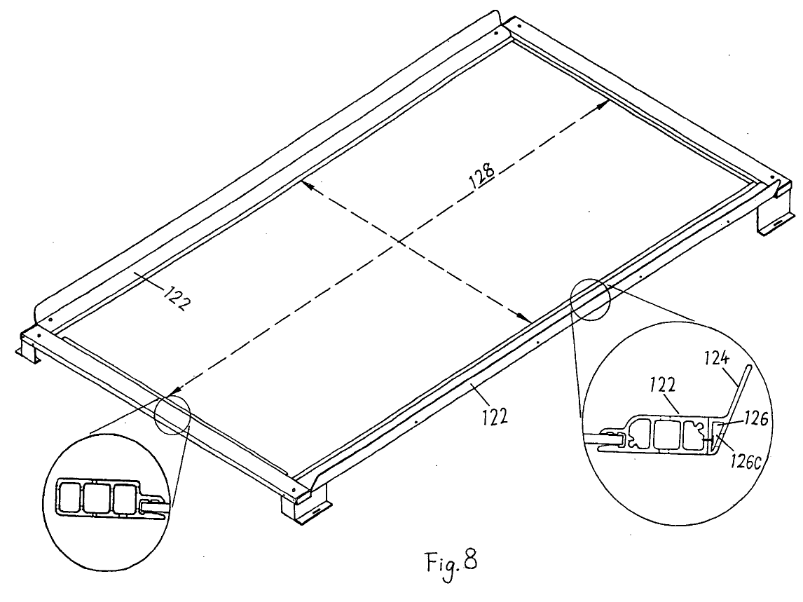

Referring now to FIG. 8, in another further alternate embodiment of the present disclosure, side elements 122 may be adapted to include attachment wings 124. Attachment wings 124 may include structural channel 126 to improve the rigidity of side elements 122 along long axis 128. Structural channel 126 may have any suitable cross-section such as triangle 126C.

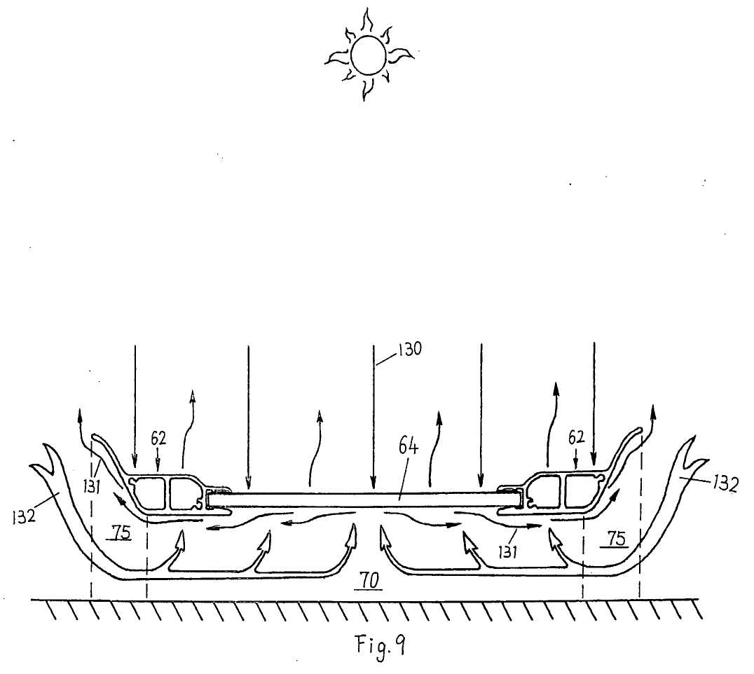

Referring now to FIG. 9, the photovoltaic frame of FIG. 3 is illustrated in a situation with little or no wind. In operation, solar radiation 130 transfers heat to cooling frame 62 and photovoltaic panels 64. Heat is transferred to surrounding air and convection flow 131 is initiated in cooling channel 70. Venturis 75 raise the speed and lower the pressure of convection flows 131 and 132.

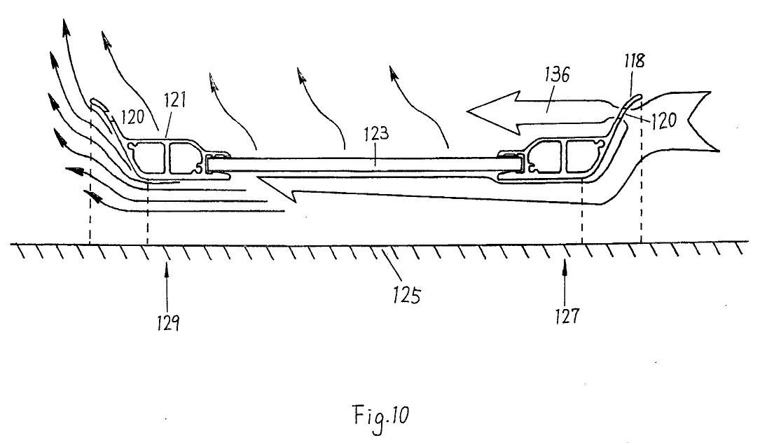

Referring now to FIG. 10, photovoltaic frame 121 of FIG. 7 is illustrated in a situation with prevailing wind 134. Vent holes 120 may be included through wing 118 parallel to prevailing wind 134 to permit a portion, or zephyr 136, of prevailing wind 134 to flow through wing 118 improving cooling of photovoltaic panel 123. In the illustrated embodiment of the present disclosure, photovoltaic panel 123 is parallel to support surface 125. It may be beneficial to slope the combined frame 121 and photovoltaic panel 123 with side 127 or side 129 closer to support surface 125 than side 129 or side 127 respectively. The slope may also be provided end to end instead of, or in addition to sloping from side to side.

Having now described the invention in accordance with the requirements of the patent statutes, those skilled in this art will understand how to make changes and modifications in the present invention to meet their specific requirements or conditions. Such changes and modifications may be made without departing from the scope and spirit of the invention as set forth in the following claims.

1. A frame for cooling and supporting one or more photovoltaic panels comprising:
two generally parallel end elements securing one or more photovoltaic panels; and
two generally parallel side elements connecting the two generally parallel end elements further securing the one or more photovoltaic panels, the two generally parallel end elements and the two generally parallel side elements forming a generally rectangular frame, each of the two side elements having a shape forming a venturi between the side element and the support surface.

2. The frame of claim 1 wherein each of the two generally parallel side elements further comprise:
two or more structural channels.

3. The frame of claim 1 wherein each of the two generally parallel end elements further comprise:
two or more structural channels.

4. The frame of claim 1 further comprising:
a wing attached to each of the two generally parallel side elements, the wing extending the venturi between the side element and the support surface.

5. The frame of claim 4 wherein each wing further comprises:
a structural channel parallel to the side element.

6. The frame of claim 1 wherein each of the two generally parallel side elements further comprise:
a wing extending from the side element forming a venturi between the side element and the support surface.

7. A frame for cooling and supporting one or more photovoltaic panels comprising:
two generally parallel side elements securing one or more photovoltaic panels; and
two generally parallel end elements connecting the two generally parallel side elements further securing the one or more photovoltaic panels, the two generally parallel side elements and the two generally parallel end elements forming a generally rectangular frame, each of the two end elements having a shape forming a venturi between the end element and the support surface.

8. The frame of claim 7 wherein each of the two generally parallel side elements further comprise:
two or more structural channels.

9. The frame of claim 7 wherein each of the two generally parallel end elements further comprise:
two or more structural channels.

10. The frame of claim 7 further comprising:
a wing attached to each of the two generally parallel end elements, the wing extending the venturi between the end element and the support surface.

11. The frame of claim 10 wherein each wing further comprises:
a structural channel parallel to the end element.

12. The frame of claim 7 wherein each of the two generally parallel end elements further comprise:
a wing extending from each of the two end elements, each wing extending the venturi between the end element and the support surface.

13. A frame for cooling and supporting one or more photovoltaic panels comprising:
two generally parallel end elements securing one or more photovoltaic panels;
two generally parallel side elements connecting the two generally parallel end elements further securing the one or more photovoltaic panels, the two generally parallel end elements and the two generally parallel side elements forming a generally rectangular frame; and
a wing extending or attached from each side element.

14. A frame for cooling and supporting one or more photovoltaic panels comprising:
two generally parallel end elements securing one or more photovoltaic panels;
two generally parallel side elements connecting the two generally parallel end elements further securing the one or more photovoltaic panels, the two generally parallel end elements and the two generally parallel side elements forming a generally rectangular frame; and
a wing extending or attached from each end element.

15. A frame for cooling and supporting one or more photovoltaic panels comprising:
two generally parallel end elements securing one or more photovoltaic panels;
two generally parallel side elements connecting the two generally parallel end elements further securing the one or more photovoltaic panels, the two generally parallel end elements and the two generally parallel side elements forming a generally rectangular frame; and
a wing extending or attached from one of the two generally parallel side elements.

16. A frame for cooling and supporting one or more photovoltaic panels comprising:
two generally parallel end elements securing one or more photovoltaic panels;
two generally parallel side elements connecting the two generally parallel end elements further securing the one or more photovoltaic panels, the two generally parallel end elements and the two generally parallel side elements forming a generally rectangular frame; and
a wing extending or attached from one of the two generally parallel end elements.

17. A frame for cooling and supporting one or more photovoltaic panels, each of the one or more photovoltaic panels having a lower surface, the frame comprising:
two generally parallel end elements securing one or more photovoltaic panels; and
two generally parallel side elements connecting the two generally parallel end elements further securing the one or more photovoltaic panels, each side element having a lower surface, the lower surfaces of the generally parallel side elements are generally coplanar, the two generally parallel end elements and the two generally parallel side elements forming a generally rectangular frame, the generally coplanar lower surfaces of the generally parallel side elements is generally coplanar with the lower surface of the one or more photovoltaic panels.

18. A frame for cooling and supporting one or more photovoltaic panels, each of the one or more photovoltaic panels having a lower surface, the frame comprising:
two generally parallel side elements securing one or more photovoltaic panels; and
two generally parallel end elements connecting the two generally parallel side elements further securing the one or more photovoltaic panels, each end element having a lower surface, the lower surfaces of the generally parallel end elements are generally coplanar, the two generally parallel side elements and the two generally parallel end elements forming a generally rectangular frame, the generally coplanar lower surfaces of the generally parallel end elements is generally coplanar with the lower surface of the one or more photovoltaic panels.

19. A frame for cooling and supporting one or more photovoltaic panels comprising:
two generally parallel end elements securing one or more photovoltaic panels; and each of the two generally parallel end elements further comprise: two or more structural channels.
two generally parallel side elements connecting the two generally parallel end elements further securing the one or more photovoltaic panels, the two generally parallel end elements and the two generally parallel side elements forming a generally rectangular frame; and each of the two generally parallel side elements further comprise: two or more structural channels.
